(19) United States
(12) Patent Application Publication
(10) Pub. No.: US 2010/0067384 A1
(43) Pub. Date: Mar. 18, 2010

(54) METHODS AND APPARATUS TO DIAGNOSE OUTBOUND VoIP SERVICES

(76) Inventors: Zhiqiang Qian, Holmdel, NJ (US); Paritosh Bajpay, Edison, NJ (US); Michael John Zinnikas, North Brunswick, NJ (US); Jackson Liu, Middletown, NJ (US)

Correspondence Address: AT&T Legal Department - HFZ;ATTN. Patent Docketing, One AT&T Way, Room 2A-207, Bedminstor, NJ, 07921, US

(21) Appl. No.: 12/209,741

(22) Filed: Sep. 12, 2008

(51) Int. Cl. G01R 31/08

(52) U.S. Cl. 370/241; 370/352

(57) ABSTRACT

Example methods and apparatus to diagnose outbound voice over Internet protocol (VoIP) services are disclosed. An example method comprises monitoring activity in a first VoIP network to determine a first value representative of a peak number of communication sessions concurrently active between a second VoIP network and a public switched telephone network via the first VoIP network, and comparing the first value to a threshold to determine whether to automatically close a trouble ticket submitted against the first VoIP network.

### FIELD OF THE DISCLOSURE

This disclosure relates generally to outbound voice over Internet protocol (VoIP) services and, more particularly, to methods and apparatus to diagnose outbound VoIP services.

### BACKGROUND

An outbound VoIP service implemented by a first VoIP network allows customers of a second VoIP network to initiate communication sessions with customers of a public-switched telephone network (PSTN) via the first VoIP network. In some instances, the operator of the second VoIP network is a wholesale customer of the operator of the first VoIP network. Generally, the operators have a wholesale relationship or agreement that specifies, limits or restricts the concurrent number of such communication sessions, and/or specifies, limits or restricts the collective durations of such communication sessions (commonly referred to as minutes of use (MOU)). When such limits are reached, the first VoIP network may block additional communication sessions, and/or cause one or more existing communication sessions to be dropped. Such blocked and/or dropped communication sessions may cause the operator of the second VoIP network to submit a trouble ticket to the operator of the first VoIP network.

### BRIEF DESCRIPTION OF THE DRAWINGS

FIG. 1 is a schematic illustration of an example communication system constructed in accordance with the teachings of this disclosure.

FIG. 2 is a flowchart representative of example machine-accessible instructions that may be executed by, for example, a processor to implement a data collector for the example communication system of FIG. 1.

FIG. 3 is a flowchart representative of example machine-accessible instructions that may be executed by, for example, a processor to implement a diagnoser for the example communication system of FIG. 1.

FIG. 4 is a schematic illustration of an example processor platform that may be used and/or programmed to carry out the example machine-accessible instructions of FIGS. 2 and/or 3, and/or to implement any or all of the example methods and apparatus described herein.

### DETAILED DESCRIPTION

Example methods and apparatus to diagnose outbound VoIP services are disclosed. A disclosed example method includes monitoring activity in a first VoIP network to determine a first value representative of a peak number of communication sessions concurrently active between a second VoIP network and a public switched telephone network via the first VoIP network, and comparing the first value to a threshold to determine whether to automatically close a trouble ticket submitted against the first VoIP network

A disclosed example apparatus includes a data collector to measure a first value representative of a peak number of communication sessions concurrently active between a first VoIP network and a public switched telephone network via a second VoIP network, and a diagnoser to compare the first value to a threshold to determine whether to automatically close a trouble ticket associated with at least one of a blocked or dropped communication session submitted against the second VoIP network by an operator of the first VoIP network.

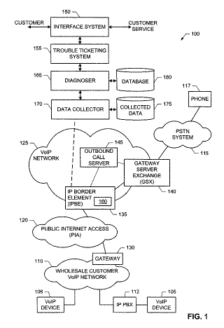

In the interest of brevity and clarity, throughout the following disclosure, references will be made to an example communication system 100 of FIG. 1 and/or to VoIP-based communication sessions. However, the methods and apparatus described herein to diagnose outbound VoIP communication sessions are applicable to other types of systems and/or networks constructed using other network technologies, topologies and/or protocols, and/or to other types of communication sessions and/or communication applications.

FIG. 1 is a schematic illustration of the example communication system 100 including any number and/or type(s) of VoIP user devices, two of which are designated at reference numerals 105 and 106. The example VoIP user devices 105 and 106 include, but are not limited to, IMS (e.g., VoIP) phones, VoIP residential gateways, VoIP enabled personal computers (PC), VoIP endpoints, wireless VoIP devices (e.g., a wireless-fidelity (WiFi) Internet protocol (IP) phone), VoIP adapters (e.g., an analog telephone adapter (ATA)), VoIP enabled personal digital assistants (PDA), and/or VoIP kiosks. The example VoIP devices 105 and 106 of FIG. 1 may be implemented and/or be found at any number and/or type(s) of locations. Further, the VoIP devices 105 and 106 may be fixed location devices, substantially fixed location devices and/or mobile devices. Moreover, the VoIP devices 105 and 106 may have equipment communicatively and/or electrically coupled to them. For example, a VoIP ATA may be coupled to a telephone, and/or a VoIP residential gateway may be coupled to a PC and/or set-top box. Further still, the example VoIP devices 105 and 106 may be associated with the same and/or different service providers. In the illustrated example of FIG. 1, the VoIP devices 105 and 106 are associated with customers of a VoIP network 110.

To provide communication services to a first set of customers and/or subscribers (e.g., those associated with the VoIP devices 105 and 106), the example communication system 100 of FIG. 1 includes the example VoIP network 110 made available by a first service provider and/or operator. In general, the example VoIP network 110 of FIG. 1 provides and/or enables VoIP-based communication services (e.g., telephone services, Internet services, data services, messaging services, instant messaging services, electronic mail (email) services, chat services, video services, audio services, gaming services, voicemail, facsimile services, etc.) to VoIP devices associated with the VoIP network 110. The example VoIP network 110 of FIG. 1 may be implemented using any number and/or type(s) of servers, devices and/or systems, which are implemented in accordance with any past, present and/or future standards and/or specifications. In some examples, a VoIP device 105, 106 may be communicatively coupled to the VoIP network 110 via an Internet protocol (IP) based private branch exchange (PBX) 112.

To provide communication services to a second set of subscribers, the example communication system 100 of FIG. 1 includes any type of PSTN system 115 made available by a second operator and/or service provider. The example PSTN system 115 of FIG. 1 may be implemented using any number and/or type(s) of servers, devices and/or systems, which are implemented in accordance with any past, present and/or future standards and/or specifications.

To allow the example VoIP devices 105 and 106 to establish communication sessions (e.g., telephone calls) with devices communicatively coupled to the example PSTN system 115 (e.g., a telephone 117), the example communication system 100 of FIG. 1 includes any type of public Internet access (PIA) network 120 and a second VoIP network 125. Using any number and/or type(s) of devices and/or technologies, the example PIA network 120 communicatively couples one or more gateways of the VoIP network 110 (e.g., a gateway 130) with one or more IP border elements (IPBEs) of the example VoIP network 125 (e.g., an IPBE 135). As illustrated in FIG. 1, the example gateway 130 and the example IPBE 135 are corresponding border elements of two different VoIP networks (e.g., the example VoIP networks 110 and 125) that are implemented by different service providers. The example gateway 130 and the example IPBE 135 of FIG. 1 implement, for example, handshaking, media translation(s) and/or protocol message modification(s) to facilitate VoIP communication sessions across and/or between the two VoIP networks 110 and 125. The example IPBE 135 of FIG. 1 is provisioned with the IP address of the gateway 130 so that, as described below, the IPBE 135 can keep track of the length of each outbound communication session and the number of concurrent outbound communication sessions initiated from the VoIP network 110 to the PSTN system 115 via the gateway 130 and the VoIP network 125.

To process, handle and/or enable communication sessions between the example VoIP network 125 and the example PSTN system 115 (and/or a public land mobile network (PLMN) such as a cellular communication network), the example VoIP network 125 of FIG. 1 includes any number and/or type(s) of gateway server exchanges (GSX) (one of which is designated at reference numeral 140) and any number and/or type(s) of outbound call servers (one of which is designated at reference numeral 145). Using any number and/or type(s) of technique(s), method(s) and/or algorithm(s), the example GSX 140 of FIG. 1 performs any necessary media data conversion(s) between, for example, a circuit-based transmission format used by the PSTN 115 and a packet-based format and/or data structure used by the VoIP network 125. The example outbound call server 145 of FIG. 1 acts as a call agent for VoIP-based communication sessions directed to and/or initiated from the PSTN system 115.

In the illustrated example of FIG. 1, the example gateway 130 and the example IPBE 135 are configured and/or implemented to facilitate communication sessions between user devices of the VoIP network 110 (e.g., any of the VoIP devices 105 and 106) and user devices of the PSTN system 115 (e.g., the telephone 117) via the intervening VoIP network 125. In the illustrated example of FIG. 1, the VoIP network 110 is operated by an outbound communication services wholesale customer of the VoIP network 125. A wholesale agreement between the operator of the VoIP network 110 and the VoIP network 125 allows users of the VoIP network 110 to make and/or receive communication sessions (e.g., telephone) calls to and/or from the PSTN system 115. When such communication sessions are initiated via the VoIP network 110 and directed to the PSTN 115, such communication sessions are referred to as outbound communication sessions with respect to the VoIP network 125. An example wholesale agreement specifies the maximum concurrent number of outbound communication sessions, and the maximum number of minutes of use (MOU) per period of time (e.g., per month) for outbound communication sessions. When either limit is exceeded, the example outbound call server 145 of FIG. 1 may optionally block additional outbound communication sessions from being initiated, and/or disconnect one or more ongoing outbound communication sessions. Such blocked and/or dropped communication sessions may cause subscribers of the VoIP network 110 to complain to the operator of the VoIP network 110. The operator of the VoIP network 110 may in response to such subscriber complaints and/or because of their independent awareness of blocked and/or dropped communication sessions submit at trouble ticket against the VoIP network 125 via an interface system 150.

When the example VoIP network 110 of FIG. 1 determines that a communication session initiated by a user device of the VoIP network 110 (e.g., the VoIP device 105) is directed to a subscriber of the PSTN system 115, the example gateway 130 routes and/or forwards a corresponding communication session initiation request to the VoIP network 125 via the PIA network 120 and the IPBE 135. The example IPBE 135 of FIG. 1 forwards the communication session initiation request to the example outbound call server 145, which is responsible for establishing the requested communication session to the PSTN system 115 via the GSX 140.

The example interface system 150 of FIG. 1 implements one or more user interfaces that allow operators (e.g., the operator of the example VoIP network 110) and/or customer service representatives (e.g., account team members) associated with the VoIP network 125 to access any type of trouble ticketing system 155. Example user interfaces are web-based interfaces that allow a user to generate, submit and/or search for trouble tickets. The example interface system 150 of FIG. 1 can also send notices (e.g., via email and/or facsimile) to operators and/or customer service representatives.

To proactively monitor for conditions that may lead to blocked and/or dropped outbound communication sessions, and/or to automatically resolve trouble tickets submitted against the VoIP network 125 for blocked and/or dropped outbound communication sessions, the example communication system 100 of FIG. 1 includes any number of monitors (one of which is designated at reference numeral 160), a data collector 170 and a diagnoser 165. Using any number and/or type(s) of method(s), logic and/or data structure(s), the example monitor 160 of FIG. 1 maintains counts of the currently active outbound communication sessions initiated by the VoIP network 110 to the PSTN system 115 for corresponding periods of time (e.g., minutes, hours, etc.). The example monitor 160 also maintains data and/or information that allow the length of outbound communication sessions to be determined.

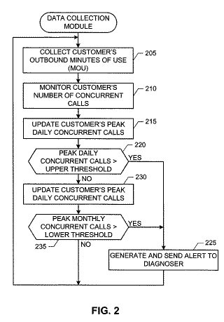

The example data collector 170 of FIG. 1 periodically or aperiodically obtains from the example monitor 160 the data collected by the monitor 160. The example data collector 170 stores the obtained information and/or data in a collected data database 175 using any number and/or type(s) of data structures. Using the information and/or data stored in the database 175, the example data collector 170 can: a) determine the peak number of concurrent outbound communication sessions during a particular period of time (e.g., a day and/or a month) and/or b) the cumulative MOU associated with all outbound communication sessions during a particular period of time (e.g., a month). When the peak number of concurrent outbound communication sessions exceeds a threshold (e.g., 95% or 60% of the maximum allowable number of concurrent outbound communication sessions), the example data collector 170 sends an alert to the example diagnoser 165. Example machine-accessible instructions that may be carried out to implement the example data collector 170 are depicted in FIG. 2.

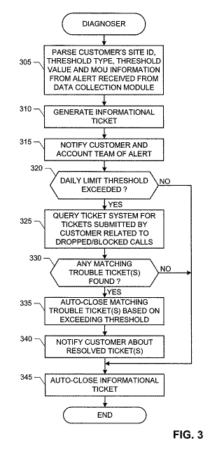

In response to an alert received from the example data collector 170, the example diagnoser 165 of FIG. 1: (a) creates an information ticket in the ticketing system 155, (b) notifies the operator of the VoIP network 110 and the account team associated with the operator, and (c) determines whether a peak number of concurrent outbound communication sessions during a particular period of time may have caused blocked and/or dropped communication sessions during that period of time. If the peak number of concurrent communication sessions may have caused blocked and/or dropped communication sessions, the diagnoser 165 queries the trouble ticketing system 155 for any dropped and/or blocked communication session trouble tickets for that particular period of time. If any such corresponding trouble tickets are found, the example diagnoser 165 automatically closes the trouble ticket(s) with a resolution that indicates the communication sessions(s) were blocked and/or dropped due to usage that exceeded one or more conditions specified in the operator's wholesale outbound communication session agreement. Results of the operations performed by the example diagnoser 165 are stored in a database 180 using any number and/or type(s) of data structures for later reuse and/or examination. Example machine-accessible instructions that may be carried out to implement the example diagnoser 165 of FIG. 1 are described below in connection with FIG. 3. The example databases 175 and 180 may be implemented using any number and/or type(s) of memory(-ies), memory device(s), volatile storage device(s), and/or non-volatile storage device(s).

While an example communication system 100 has been illustrated in FIG. 1, one or more of the interfaces, data structures, elements, processes and/or devices illustrated in FIG. 1 may be combined, divided, re-arranged, omitted, eliminated and/or implemented in any other way. Further, the example IPBE 135, the example GSX 140, the example outbound call server 145, the example trouble ticket system 155, the example diagnoser 165, the example data collector 170 and/or the example collected data database 175 of FIG. 1 may be implemented by hardware, software, firmware and/or any combination of hardware, software and/or firmware. Thus, for example, any or the example IPBE 135, the example GSX 140, the example outbound call server 145, the example trouble ticket system 155, the example diagnoser 165, the example data collector 170 and/or the example collected data database 175 may be implemented by one or more circuit(s), programmable processor(s), application specific integrated circuit(s) (ASIC(s)), programmable logic device(s) (PLD(s)) and/or field programmable logic device(s) (FPLD(s)), etc. When any of the appended claims are read to cover a purely software and/or firmware implementation, at least one of the example IPBE 135, the example GSX 140, the example outbound call server 145, the example trouble ticket system 155, the example diagnoser 165, the example data collector 170 and/or the example collected data database 175 are hereby expressly defined to include a tangible medium such as a memory, a digital versatile disc (DVD), a compact disc (CD), etc. storing the firmware and/or software. Further still, a communication system may include interfaces, data structures, elements, processes and/or devices instead of, or in addition to, those illustrated in FIG. 1 and/or may include more than one of any or all of the illustrated interfaces, data structures, elements, processes and/or devices.

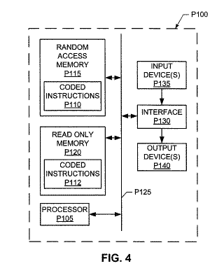

FIG. 2 illustrates example machine-accessible instructions that may be executed to implement the example data collector 170 of FIG. 1. FIG. 3 illustrates example machine-accessible instructions that may be executed to implement the example diagnoser 165 of FIG. 1. The example machine-accessible instructions of FIGS. 2 and/or 3 may be carried out by a processor, a controller and/or any other suitable processing device. For example, the example machine-accessible instructions of FIGS. 2 and/or 3 may be embodied in coded instructions stored on any tangible computer-readable medium such as a flash memory, a CD, a DVD, a floppy disk, a read-only memory (ROM), a random-access memory (RAM), a programmable ROM (PROM), an electronically-programmable ROM (EPROM), and/or an electronically-erasable PROM (EEPROM), an optical storage disk, an optical storage device, magnetic storage disk, a magnetic storage device, and/or any other medium which can be used to carry or store program code and/or instructions in the form of machine-readable instructions or data structures, and which can be accessed by a processor, a general-purpose or special-purpose computer, or other machine with a processor (e.g., the example processor platform P100 discussed below in connection with FIG. 4). Combinations of the above are also included within the scope of computer-readable media. Machine-readable instructions comprise, for example, instructions and/or data that cause a processor, a general-purpose computer, special-purpose computer, or a special-purpose processing machine to implement one or more particular processes. Alternatively, some or all of the example machine-accessible instructions of FIGS. 2 and/or 3 may be implemented using any combination(s) of ASIC(s), PLD(s), FPLD(s), discrete logic, hardware, firmware, etc. Also, some or all of the example machine-accessible instructions of FIGS. 2 and/or 3 may instead be implemented manually or as any combination of any of the foregoing techniques, for example, any combination of firmware, software, discrete logic and/or hardware. Further, many other methods of implementing the example operations of FIGS. 2 and/or 3 may be employed. For example, the order of execution of the blocks may be changed, and/or one or more of the blocks described may be changed, eliminated, sub-divided, or combined. Additionally, any or all of the example machine-accessible instructions of FIGS. 2 and/or 3 may be carried out sequentially and/or carried out in parallel by, for example, separate processing threads, processors, devices, discrete logic, circuits, etc.

The example machine-accessible instructions of FIG. 2 begin with the example data collector 170 of FIG. 1 collecting MOU data and/or information from the example monitor 160 for a particular wholesale customer (block 205) and collecting number of concurrent calls data from the monitor 160 for the customer (block 210). Using the collected number current calls data, the data collector 170 determines the customer's peak number of concurrent calls for the past 24 hours (block 215). If the peak number of concurrent calls exceeds a threshold (e.g., 95% of the maximum allowable concurrent calls specified in the customer's wholesale agreement) (block 220), the data collector 170 generates and sends an alert to the example diagnoser 165 (block 225). Control then returns to block 205 to collect additional data and/or information from the monitor 160 for the same and/or a different wholesale customer.

Returning to block 220, if the peak number of concurrent calls did not exceed the threshold (block 220), the data collector 170 determines the wholesale customer's peak number of concurrent calls over the past month (block 230). If the peak number of concurrent calls over the past month exceeds a second threshold (e.g., 60% of the maximum allowable concurrent calls specified in the customer's wholesale agreement) (block 235), the data collector 170 generates and sends an alert to the example diagnoser 165 (block 225). Control then returns to block 205 to collect additional data and/or information from the monitor 160 for the same and/or a different wholesale customer. If the peak number of concurrent calls over the past month does not exceed the second threshold (block 235), control returns to block 205 without sending an alert.

The example machine-accessible instructions of FIG. 3 begin when the diagnoser 165 receives an alert from the example data collector 170. The example diagnoser 165 parses information from the alert (block 305). Example information included in the alert includes, but is not limited to, the type of value compared (e.g., peak daily concurrent number of calls), threshold value used (e.g., 95% or 60% of maximum allowable value), and/or MOU data. The example diagnoser 165 generates an information ticket in the example ticketing system 155 (block 310). The information ticket includes information and/or data related to the alert received by the diagnoser 165. The diagnoser 165 also notifies the wholesale customer and the account team responsible for the wholesale customer of the alert and the informational ticket (block 315).

If the alert indicated that the peak daily concurrent number of calls exceeded the 95% threshold (block 320), the diagnoser 165 queries the ticketing system 155 for any trouble tickets related to blocked and/or dropped communication sessions that correlate with the day during which the peak daily concurrent number of calls exceeded the 95% threshold (block 325). If any matching trouble tickets are located (block 330), the diagnoser 165 automatically closes the trouble ticket(s) with a resolution that indicates the communication sessions(s) were blocked and/or dropped due to usage that exceeded one or more conditions specified in the operator's wholesale outbound communication session agreement (block 335). The example ticketing system 155 notifies the wholesale customer that the ticket(s) were automatically closed via the example interface system 150 (block 340). The diagnoser updates the informational ticket to indicate whether any trouble tickets were automatically closed, and closes and submits the informational ticket (block 345). Control then exits from the example machine-accessible instructions of FIG. 3.

Returning to block 330, if no matching trouble tickets were located (block 330), control proceeds to block 345 without closing any trouble tickets.

Returning to block 320, if the alert indicated that the peak daily concurrent number of calls did not exceed the 95% threshold (block 320), control proceeds to block 345 without querying for any trouble tickets.

FIG. 4 is a schematic diagram of an example processor platform P100 that may be used and/or programmed to implement any or all of the example IPBE 135, the example monitor 160, the example outbound call server 145, the example GSX 140, the example interface system 150, the example trouble ticketing system 155, the example diagnoser 165 and/or the example data collector 170 of FIG. 1. For example, the processor platform P100 can be implemented by one or more general-purpose processors, processor cores, microcontrollers, etc.

The processor platform P100 of the example of FIG. 4 includes at least one general-purpose programmable processor P105. The processor P105 executes coded instructions P110 and/or P112 present in main memory of the processor P105 (e.g., within a RAM P115 and/or a ROM P120). The processor P105 may be any type of processing unit, such as a processor core, a processor and/or a microcontroller. The processor P105 may execute, among other things, the example machine-accessible instructions of FIGS. 2 and/or 3 to implement the example methods and apparatus described herein.

The processor P105 is in communication with the main memory (including a ROM P120 and/or the RAM P115) via a bus P125. The RAM P115 may be implemented by dynamic random access memory (DRAM), synchronous dynamic random access memory (SDRAM), and/or any other type of RAM device, and ROM may be implemented by flash memory and/or any other desired type of memory device. Access to the memory P115 and the memory P120 may be controlled by a memory controller (not shown). The example memory P115 may be used to implement the example databases 175 and/or 180 of FIG. 1.

The processor platform P100 also includes an interface circuit P130. The interface circuit P130 may be implemented by any type of interface standard, such as an external memory interface, serial port, general-purpose input/output, etc. One or more input devices P135 and one or more output devices P140 are connected to the interface circuit P130.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A method comprising:
monitoring activity in a first voice over Internet protocol (VoIP) network to determine a first value representative of a peak number of communication sessions concurrently active between a second VoIP network and a public switched telephone network via the first VoIP network; and
comparing the first value to a threshold to determine whether to automatically close a trouble ticket submitted against the first VoIP network.

2. A method as defined in claim 1, further comprising:
determining a second value representative of a second peak number of communication sessions concurrently active between the second VoIP network and the PSTN via the first VoIP network, the first value is determined over a day, and the second value determined over a month;
updating a third value representative of minutes of use based on durations of respective ones of the concurrently active communication sessions; and
comparing the second value to a second threshold to determine whether to generate an information ticket having the first value, the second value, the third value, and a fourth value representative of the second VoIP network.

3. A method as defined in claim 1, further comprising generating an information ticket having the first value and a second value representative of the second VoIP network.

4. A method as defined in claim 3, further comprising updating a third value representative of minutes of use based on durations of respective ones of the concurrently active communication sessions, wherein the information ticket includes the third value.

5. A method as defined in claim 1, further comprising alerting an operator associated with the second VoIP network and a customer support representative associated with the first VoIP network when the first value exceeds the threshold.

6. A method as defined in claim 1, further comprising adding a note to the automatically closed trouble ticket indicating that the trouble ticket was closed because the first value exceeded the threshold.

7. A method as defined in claim 1, wherein the threshold represents 95% of a maximum allowed number of concurrent communication sessions.

8. A method as defined in claim 1, wherein the trouble ticket is associated with at least one of a dropped or blocked communication session.

9. A method as defined in claim 1, wherein the trouble ticket is submitted against the first VoIP network by an operator of the second VoIP network.

10. An apparatus comprising:
a data collector to measure a first value representative of a peak number of communication sessions concurrently active between a first voice over Internet protocol (VoIP) network and a public switched telephone network via a second VoIP network; and
a diagnoser to compare the first value to a threshold to determine whether to automatically close a trouble ticket associated with at least one of a blocked or dropped communication session submitted against the second VoIP network by an operator of the first VoIP network.

11. An apparatus as defined in claim 10, further comprising a monitor to update a third value representative of minutes of use based on durations of respective ones of the concurrently active communication sessions, wherein the diagnoser is to add the second value to the automatically closed trouble ticket.

12. An apparatus as defined in claim 11, wherein the data collector is to measure a third value representative of a second peak number of communication sessions concurrently active between the first VoIP network and the PSTN via the second VoIP network, the first value measured over a day, and wherein the third value measured over a month; and the diagnoser is to compare the second value to a second threshold to determine whether to generate an information ticket having the first value, the second value, the third value, and a fourth value representative of the first VoIP network.

13. An apparatus as defined in claim 11, wherein the diagnoser is to generate an information ticket having the first value and a second value representative of the first VoIP network.

14. An apparatus as defined in claim 11, wherein the diagnoser is to alert an operator associated with the first VoIP network and a customer support representative associated with the second VoIP network when the first value exceeds the threshold.

15. An apparatus as defined in claim 11, wherein the diagnoser is to add a note to the automatically closed trouble ticket indicating that the trouble ticket was closed because the first value exceeded the threshold.

16. An apparatus as defined in claim 11, wherein the threshold represents 95% of a maximum allowed number of concurrent communication sessions.

17. An article of manufacture storing machine readable instructions which, when executed, cause a machine to:
monitor activity in a first voice over Internet protocol (VoIP) network to determine a first value representative of a peak number of communication sessions concurrently active between a second VoIP network and a public switched telephone network via the first VoIP network; and
compare the first value to a threshold to determine whether to automatically close a trouble ticket submitted against the first VoIP network.

18. An article of manufacture as defined in claim 17, wherein the machine readable instructions, when executed, cause the machine to:
determine a second value representative of a second peak number of communication sessions concurrently active between the second VoIP network and the PSTN via the first VoIP network, the first value is determined over a day, and the second value determined over a month;
update a third value representative of minutes of use based on durations of respective ones of the concurrently active communication sessions; and
compare the second value to a second threshold to determine whether to generate an information ticket having the first value, the second value, the third value, and a fourth value representative of the second VoIP network.

19. An article of manufacture as defined in claim 17, wherein the machine readable instructions, when executed, cause the machine to generate an information ticket having the first value and a second value representative of the second VoIP network.

20. An article of manufacture as defined in claim 19, wherein the machine readable instructions, when executed, cause the machine to update a third value representative of minutes of use based on durations of respective ones of the concurrently active communication sessions, wherein the information ticket includes the third value.

21. An article of manufacture as defined in claim 17, wherein the machine readable instructions, when executed, cause the machine to alert an operator associated with the second VoIP network and a customer support representative associated with the first VoIP network when the first value exceeds the threshold.

22. An article of manufacture as defined in claim 17, wherein the machine readable instructions, when executed, cause the machine to add a note to the automatically closed trouble ticket indicating that the trouble ticket was closed because the first value exceeded the threshold.
